(19) United States
(12) Patent Application Publication
(10) Pub. No.: US 2010/0299091 A1
(43) Pub. Date: Nov. 25, 2010

(54) MULTI-FUNCTION PORTABLE ELECTRONIC DEVICE

(75) Inventors: YONG-JUN XIA, Shenzhen City (CN); WU YANG, Shenzhen City (CN); QI-JING WU, Shenzhen City (CN)

Correspondence Address: Altis Law Group, Inc.;ATTN: Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/510,768

(22) Filed: Jul. 28, 2009

(30) Foreign Application Priority Data
May 20, 2009 (CN) 200910302475.5

(51) Int. Cl. G01R 27/08

(52) U.S. Cl. 702/65

(57) ABSTRACT

An exemplary multi-function portable electronic device includes a housing, a measurement processing unit, a microprocessor unit electrically connected to the measurement processing unit and a command unit. The measurement processing unit and the microprocessor unit are located in the housing, and the command unit is located in the housing and electrically connected to microprocessor unit. The command unit is used to start a multimeter mode of the portable electronic device, select a measurement project and measurement range of the measurement project. Under the control of the microprocessor, the measurement processing unit receives and processes the measurement project in accordance with the measurement range, and sends measurement results to the microprocessor.

### BACKGROUND

1. Technical Field

The disclosure relates to portable electronic devices, particularly, to a multi-function portable electronic device.

2. Description of Related Art

Nowadays, multimeters have important roles in electrical and electronic measurement technology. Multimeters are often used to measure voltage, current, and resistance of electrical and electronic circuits or components and so are very useful. However, most people now already carry other personal electronic devices such as mobile phones, calculators etc. Therefore, a need exists to combine functions of various electronic devices so that people don't have to carry so many devices on their person.

### BRIEF DESCRIPTION OF THE DRAWINGS

Many aspects of a multi-function portable electronic device can be better understood with reference to the following drawings. The components in the drawings are not necessarily to scale, the emphasis instead being placed upon clearly illustrating the principles of the present multi-function portable electronic device. Moreover, in the drawings, like reference numerals designate corresponding parts throughout the several views.

FIG. 1 is a schematic view of a multi-function electronic portable having two test probes according to an exemplary embodiment.

FIG. 2 is a block view of the multi-function portable electronic device shown in FIG. 1.

### DETAILED DESCRIPTION OF THE EMBODIMENTS

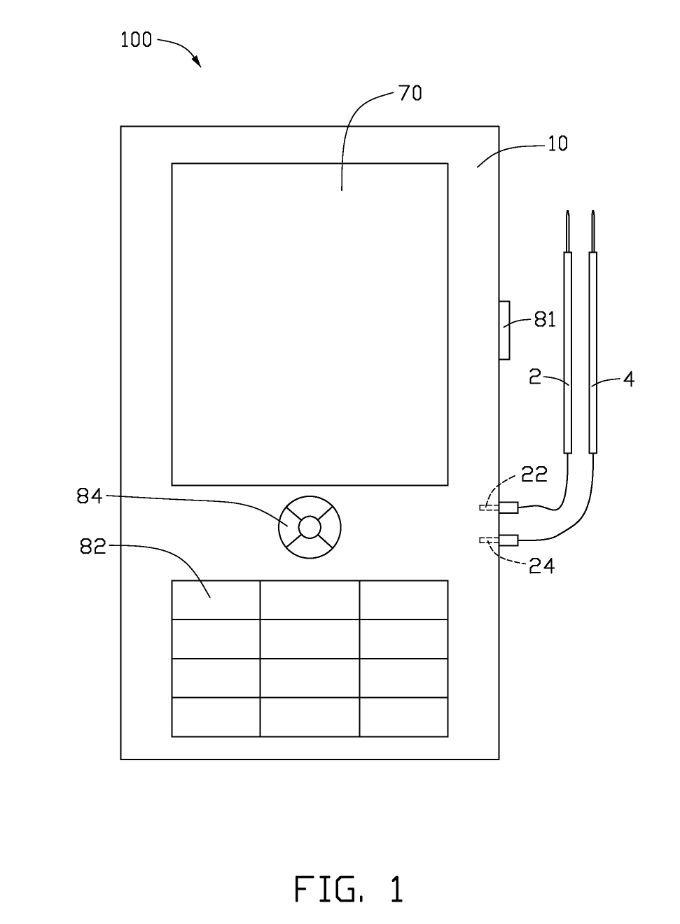

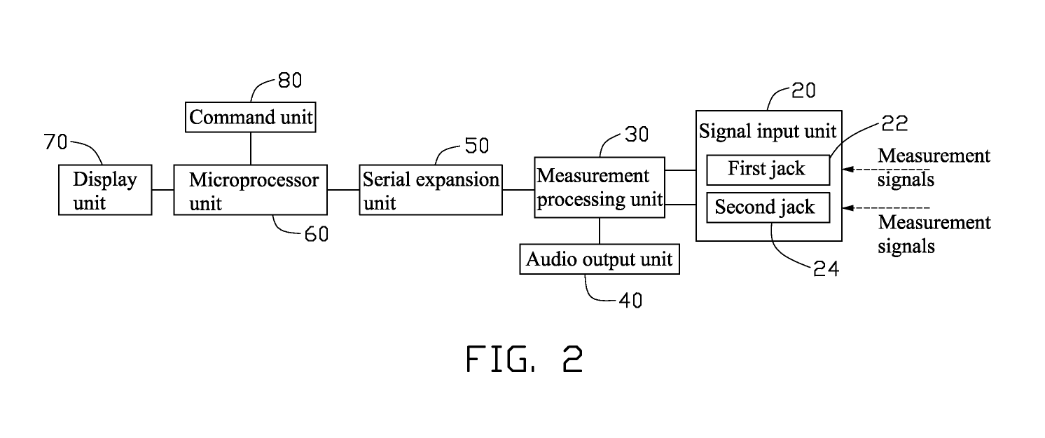

Referring to FIGS. 1-2, the disclosure relates to a multi-function portable electronic device 100, which may be a mobile phone, a PDA and so on, but illustrating a mobile phone as an example.

The multi-function portable electronic device 100 includes a housing 10, a signal input unit 20, a measurement processing unit 30, an audio output unit 40, a serial expansion unit 50, a microprocessor unit 60, a display unit 70, and a command unit 80. The signal input unit 20, the measurement processing unit 30, the serial expansion unit 50, the microprocessor unit 60, and the display unit 70 are electrically connected in series, the audio output unit 40 is electrically connected to the measurement unit 30, and the command unit 80 is electrically connected to the microprocessor unit 60.

The signal input unit 20 includes a first jack 22 and a second jack 24, and the first jack 22 and the second jack 24 may be located on an exterior surface the housing 10 to be conveniently operated. The first jack 22 is used to connect a connection end of a black test probe 2, which is used to be connected to the GND. The second jack 24 is used to be connected to a signal input device such as a red test probe 4, so that the signal input device can receive signals, such as AC (alternating current)/DC (direct current) voltage, AC/DC current and so on, and send the signals to the second jack 24.

The measurement processing unit 30 can use an existing digital multimeter chip, such as an NJU9207, an NJU9208 and so on, which can collect data and convert analog signals into digital signals etc. The measurement processing unit 30 is used to measure AC/DC voltage, AC/DC current, resistance and other electrical parameters according to the signals from the signal input unit 20, and can also be used to test for short-circuits, polarity etc.

The audio output unit 40 is used to output warning signals as controlled by the measurement processing unit 30 to alert users to such things as short-circuits and voltages or currents exceeding the measurement range. It is to be understood, however, that in addition to being able to output alarm signals, the portable electronic device 100 can also output different frequency vibrations to inform the users. Furthermore, some indicators may be set on the housing 10, with different colors indicating different measurement states, such as red denoting an abnormal state and green denoting a normal state. The audio output unit 40 also outputs audio signals having different frequencies for users to express different measurement states.

The serial expansion unit 50 can be integrated with an existing input/output expander, such as a 8255A, a PCA959 and a PCA9535. The serial expansion unit 50 may be integrated with an existing I/O expander, such as the 8255A, a PCA959 and a PCA9535. The serial expansion unit 50 may use the general purpose input/output (GPIO) port of the measurement processing unit 30 to connect and convert electrical signals between the measurement processing unit 30 and the microprocessor unit 60.

The microprocessor unit 60 can be an existing central process unit (CPU), such as a MT6223C, of the portable electronic device 100 and be used not only to accomplish measuring tasks but for general functions of the portable electronic device 100 as well.

In addition to showing telephone numbers, short messages and other general information, the display unit 70 is also used to show varieties of operating instructions and different measurement results, such as the voltage, current resistance, short circuits, diode detection, etc. The exemplary embodiment of the display unit 70 is an existing display module of the portable electronic device 100, such as a touch LCD (liquid crystal display) screen, a LCM (LCD module) and so on.

The command unit 80 can be integrated with an existing command input device, such as a control panel, a keyboard module, etc. The command unit 80 may include a start button 81 for starting the multimeter mode of the portable electronic device 100, a plurality of numeric keys 82, and a direction key 84. The start button 81 may be conveniently located on an exterior surface of the housing 10. When the user operates the start button 81, the start button 81 sends an electric signal to the microprocessor unit 60, then the portable electronic device 100 enters the multimeter mode.

The numeric keys 82 are used to select a measurement project. When the user operates each numeric key 82, the numeric key 82 sends an electric signal to the microprocessor unit 60, and then microprocessor unit 60 controls the measurement processing unit 30 to select a measurement project. For example, operating the numeric key “1” selects DC voltage measurement, operating the numeric key “2” selects AC voltage measurement, operating the numeric key “3” selects resistance measurement, operating the numeric key “4” selects DC current measurement, operating the numeric key “5” selects AC current measurement, and so on. Once a choice is selected through operating the numeric key 82, the display unit 70 displays a corresponding choice menu showing different measurement ranges, then the user operates the direction key 84 to choose the different measurement ranges such 5-100 volts. The exemplary embodiment of the plurality of numeric keys 82 and the direction key 84 can be the existing keyboard devices of the portable electronic device 100. It is to be understood, however, that the portable electronic device 100 can not only be indirectly started the multimeter mode by operating the direction key 84 to select a multimeter function menu on the display unit 70, but also be directly started the multimeter mode by operating the start button 81.

When the multi-function portable electronic device 100 is used to measure AC/DC voltage, AC/DC current, and resistance, the portable electronic device 100 is first set to the multimeter mode. Then a type of measurement is chosen by operating a corresponding numeric key 82, and a measurement range is chosen by operating the direction key 84. Then the signal input devices, such as the black test probe 2 and the red test probe 4, are respectively inserted into the first jack 22 and the second jack 24 and contact ends of the probes 2, 4 used to measure the selected electrical parameter. After that, the measurement results are directly displayed on the display unit 70. If a short-circuit is detected, or the measurement range selected is too small, then the audio output unit 40 outputs warning sounds to alert the user, and the measurement range can be changed.

When one measurement project is completed, another measurement project can be selected by operating another corresponding numeric key 82, then a corresponding measurement range is selected. The black test probe 2 and the red test probe 4 then are connected to the other electronic components or circuits, and then the measurement results displayed on the display unit 70.

The signal input unit 20 of the portable electronic device 100 receives the signals to be measured, such as AC/DC voltage and current, and sends the signals to the measurement unit 30. The microprocessor unit 60 controls the measurement processing unit 30 to measure the AC/DC voltage, AC/DC current and other electronic parameters. The multi-function portable electronic device 100 integrates the multimeter function with existing portable electronic devices, and the functions of the existing portable electronic devices are further expanded to be used widely. The multi-function portable electronic device 100 in actual use is simple to operate, easy to carry, and meets the needs of the users.

It is to be understood, however, that even through numerous characteristics and advantages of the present disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A multi-function portable electronic device, comprising:
a housing having an exterior wall;
a command unit located at least partially outside of the housing and used to start a multimeter mode of the portable electronic device and select a measurement project;
a microprocessor unit located in the housing and electrically connected to the command unit; and
a measurement processing unit located in the housing and controlled by the microprocessor unit to measure a parameter;
wherein when the portable electronic device enters the multimeter mode and the measurement project is selected, a measurement range of the measurement project is selected using the command unit, the measurement processing unit receives and processes the measurement project in accordance with the measurement range, and sends measurement results to the microprocessor unit.

2. The multi-function portable electronic device as claimed in claim 1, wherein the measurement project selected by the command unit is at least one of AC/DC voltage, AC/DC current, resistance, short-circuit detection and diode detection.

3. The multi-function portable electronic device as claimed in claim 2, further including a signal input unit electrically connected to the measurement processing unit, wherein the signal input unit is used to receive a signal to be measured of the AC/DC voltage, AC/DC current, resistance, short-circuit detection or diode detection and send the signal to the measurement processing unit.

4. The multi-function portable electronic device as claimed in claim 3, wherein the signal input unit includes a first jack and a second jack both located on the exterior wall of the housing, and connected to the measurement processing unit, the signal to be measured is received by the signal input unit and sent to the measurement processing unit.

5. The multi-function portable electronic device as claimed in claim 1, wherein the command unit includes an start button for starting the multimeter mode of the portable electronic device, the start button is located at least partially outside of the housing and sends a control signal to the microprocessor to control the portable electronic device to enter the multimeter mode.

6. The multi-function portable electronic device as claimed in claim 5, wherein the command unit further includes a plurality of numeric keys located at least partially outside of the housing, at least one of the numeric keys is associated with and is used to select a corresponding measurement project.

7. The multi-function portable electronic device as claimed in claim 6, wherein the command unit further includes a direction key located at least partially outside of the housing, when a measurement project is selected using a numeric key, the direction key is used to select a measurement range of the measurement project.

8. The multi-function portable electronic device as claimed in claim 1, further including an audio output unit electrically connected to the measurement processing unit, wherein the audio output unit outputs corresponding warning signals when the measurement results are abnormal.

9. The multi-function portable electronic device as claimed in claim 1, further including a display unit electrically connected to the microprocessor unit, the measurement results are displayed on the display unit.

10. The multi-function portable electronic device as claimed in claim 1, further including a serial expansion unit to electrically connect and convert electrical signals between the measurement processing unit and the microprocessor unit.

11. A multi-function portable electronic device, comprising:
a housing having an exterior wall;
a command unit located at least partially outside of the housing and used to start a multimeter mode of the portable electronic device and select a measurement project;
a microprocessor unit located in the housing and electrically connected to the command unit; and
a measurement processing unit located in the housing and controlled by the microprocessor unit to measure a parameter;
a signal input unit to receive a signal corresponding to the measurement project to be measured;
a measurement processing unit located in the housing, electrically connected to the signal input unit for receiving the signal to be measured, and controlled by the microprocessor unit to measure the signal;
wherein when the portable electronic device enters the multimeter mode and the measurement project is selected, a measurement range of the measurement project is selected using the command unit, the signal input unit receives the signal to be measured and sends the signal to the measurement processing unit, the measurement processing unit receives and processes the signal corresponding to the measurement project in accordance with the measurement range, and sends measurement results to the microprocessor.

12. The multi-function portable electronic device as claimed in claim 11, wherein the measurement project selected by the command unit is at least one of AC/DC voltage, AC/DC current, resistance, short-circuit detection or diode detection.

13. The multi-function portable electronic device as claimed in claim 11, wherein the signal input unit includes a first jack and a second jack both located on the exterior wall of the housing, and connected to the measurement processing unit, the signal to be measured is received by the signal input unit and sent to the measurement processing unit.

14. The multi-function portable electronic device as claimed in claim 11, wherein the command unit includes an start button for starting the multimeter mode of the portable electronic device, the start button is located at least partially outside of the housing and when the start button is operated, a control signal is sent to the microprocessor unit to control the portable electronic device to enter the multimeter mode.

15. The multi-function portable electronic device as claimed in claim 14, wherein the command unit further includes a plurality of numeric keys located at least partially outside of the housing, at least one of the numeric keys is associated with and is used to select a corresponding measurement project.

16. The multi-function portable electronic device as claimed in claim 14, wherein the command unit further includes a direction key located at least partially outside of the housing, when a measurement project is selected using a numeric key, the direction key is used to select the measurement range of the measurement project.

17. The multi-function portable electronic device as claimed in claim 11, further including an audio output unit electrically connected to the measurement processing unit, the audio output unit outputs corresponding warning signals when the measurement results are abnormal.

18. The multi-function portable electronic device as claimed in claim 11, further including a display unit electrically connected to the microprocessor unit.

19. The multi-function portable electronic device as claimed in claim 11, further including a serial expansion unit to electrically connect and convert electrical signals between the measurement processing unit and the microprocessor unit.
